(19) United States
(12) Patent Application Publication
(10) Pub. No.: US 2010/0295173 A1
(43) Pub. Date: Nov. 25, 2010

(54) Composite Underfill and Semiconductor Package

(75) Inventors: Hui-Lin Chang, Hsin-Chu (TW); Chih-Lung Lin, Taipei (TW); Syun-Ming Jang, Hsin-Chu (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd., Hsin-Chu (TW)

(21) Appl. No.: 12/714,209

(22) Filed: Feb. 26, 2010

Related U.S. Application Data
(60) Provisional application No. 61/180,300, filed on May 21, 2009.

(51) Int. Cl. H01L 23/488; H01L 21/56; H01L 23/31; C08K 3/28; C08K 3/34; C08K 3/08; C08K 3/04

(52) U.S. Cl. 257/737; 438/124; 524/424; 524/443; 524/440; 977/700; 257/795; 257/E21.503; 257/E23.023; 257/E23.129; 977/752

(57) ABSTRACT

Embodiments of the invention exploit physical properties of nanostructures by using nanostructures in a composite underfill. An embodiment is a composite underfill comprising an epoxy matrix applied between a substrate and a semiconductor chip and a suspension of nanostructures distributed within the epoxy matrix. Another embodiment is a semiconductor package comprising a semiconductor chip, a carrier, wherein the semiconductor chip is bonded to the carrier, and a composite underfill comprising a plurality of nanostructures dispersed in an epoxy medium between the carrier and the semiconductor chip. Further embodiments include a method for creating a semiconductor package comprising a composite underfill.

This application claims the benefit of U.S. Provisional Patent Application Ser. No. 61/180,300, filed on May 21, 2009, and entitled “Composite Underfill and Semiconductor Package,” which application is incorporated herein by reference.

### TECHNICAL FIELD

The present invention relates generally to underfill in semiconductor packages, and more particularly to a composite underfill, a semiconductor package, and a method for creating a semiconductor package.

### BACKGROUND

Generally in flip chip technology, underfill between a semiconductor chip and a carrier is used to increase the reliability of the package by reducing stresses on solder bumps. Yet, underfill can be improved to further the goals of conventional underfill.

A flip chip assembly includes a direct electrical connection of a downward facing (that is, “flipped”) semiconductor chip, or die, onto a carrier, such as a ceramic substrate or a circuit board, using conductive bump bond pads of the chip. Flip chip assemblies are typically made by placing solder bumps on the bump bond pads of the chip, attaching the solder bumped chip to a carrier, and applying an adhesive underfill between the chip and the carrier. Examples of conventional underfill are the 3730 from Hitachi and the UA28 from Namics.

The bumps of the flip chip assembly serve several functions but are susceptible to failures caused by stresses. Of those functions, the bumps provide electrical conductive paths from the chip to the substrate on which the chip is mounted. The bumps also provide part of the mechanical mounting of the chip to the substrate. Unfortunately, bumps are prone to cracking generally caused by stresses, including stress caused by thermal expansion mismatch between the chip and the carrier substrate. The significant difference of coefficients of thermal expansion introduces stress to the structure when thermal change occurs. FIG. 1A illustrates a chip 2 mounted on a carrier 4 by solder bumps 8 at a thermal equilibrium. FIG. 1B illustrates the chip 2′, the carrier 4′, and the bumps 8′ after being heated to a temperature higher than the thermal equilibrium. The chip 2′ expands a length Δl_{FC}, and the carrier 4′ expands a length Δl_{C}. The difference between these two lengths results in a stress on the bumps 8′ that can result in cracks or other failures.

One solution to the problem caused by differences in coefficients of thermal expansion is to fill the gap between the chip and the substrate using an epoxy underfill. FIG. 2A illustrates the addition of underfill 6 between the chip 2 and carrier 4 and around the bumps 8. Underfill helps spread the stress and protect the solder bumps. But sometimes the underfill has a high coefficient of thermal expansion that creates a mismatch between the expansion of the chip and the underfill. This mismatch introduces more stress in the package that can result in failures. This is shown in FIG. 2B where the underfill 6″ expands at a greater rate than the other components in the package. The underfill 6″ can bubble out from between the chip 2″ and the carrier 4″ possibly causing cracking or delamination of the chip 2″. Further, the underfill 6″ could expand a height Δh_{U} causing greater stress on the bumps 8″.

With low-k dielectrics widely used in a chip, a dilemma exists between the protection of bumps and low-k dielectrics. The protection of brittle bumps demands a high strength underfill. However, the low-k dielectrics may be harmed by high strength underfill material such that problems like delamination occur. To protect the low-k dielectric layers, the underfill preferably has a low glass transition temperature (Tg). Low-Tg underfills become soft at relatively low temperatures. When the temperature of the chip rises, the modulus of underfill decreases so that the stress applied on the low-k dielectric materials is released. However, with lower modulus, the protection provided by low-Tg underfill to the solder bumps is reduced, subjecting solder bumps to cracking that may result in an open circuit. View 10 in FIG. 3 illustrates a crack 12 in the low-k dielectric layer of the chip 2 when the underfill 6 has a high-Tg temperature. View 14 illustrates a crack 16 in a bump 8 when the underfill 6 has a low-Tg temperature.

The low-k dielectric can crack from thermal fatigue induced by the underfill not conducting heat energy away from the chip. Further, the low-k dielectric can crack from the mismatch of coefficients of thermal expansion, as stated above.

Conventional underfill is not always effective in spreading the stress to protect solder bumps because of voids or settling. Sometimes, voids in the underfill occur adjacent to a solder bump because of the pitch of the solder bump at the bump bond pads. If the space between the bump and the chip is too small near the joint, the particles of the underfill will be too large to fill the space, and a void will occur. View 18 of FIG. 4 illustrates an example of a void 20 adjacent to the joint of the bump 8 and the bond pad (not illustrated) of the chip 2. Voids will prevent the underfill from distributing stress and will weaken a package at the voids. Further, sometimes particles, such as silica, are mixed with underfill. If the particles settle, or do not remain suspended uniformly throughout the underfill, during the curing process, the underfill is weakened. View 22 in FIG. 4 shows settling of the particles 24 in the underfill 6.

Also, conventional underfill generally does not have good moisture resistance. If moisture is able to penetrate the underfill, the solder bumps could become electrically connected to each other causing a short circuit. A short circuit could lead to failure of the entire package.

Thus, what is needed is an improved underfill that can overcome the above shortcomings in the prior art.

### SUMMARY OF THE INVENTION

These and other problems are generally solved or circumvented, and technical advantages are generally achieved, by embodiments of the present invention that exploit physical properties of nanostructures by creating a composite underfill comprising nanostructures.

In accordance with an embodiment of the present invention, a composite underfill comprises an epoxy matrix applied between a substrate and a semiconductor chip and a suspension of nanostructures distributed within the epoxy matrix.

In accordance with another embodiment of the present invention, a semiconductor package comprising a semiconductor die, a substrate, wherein the semiconductor die is electrically coupled to the substrate by solder bumps, and a composite underfill comprising nanostructures dispersed in an epoxy, wherein the composite underfill is between the semiconductor die and the substrate and around the solder bumps.

In accordance with another embodiment of the present invention, a semiconductor package comprises a semiconductor chip, a carrier, wherein the semiconductor chip is bonded to the carrier, and a composite underfill comprising a plurality of nanostructures dispersed in an epoxy medium between the carrier and the semiconductor chip.

In accordance with another embodiment of the present invention, a method for creating a semiconductor package comprises creating solder bumps on a semiconductor chip, bonding the bumps to a carrier, applying a composite underfill comprising nanostructures, and curing the composite underfill.

Advantages of embodiments of the present invention are better coefficients of thermal expansion matching between the semiconductor chip and the underfill, a higher glass transition temperature of the underfill, better thermal integrity, decreases in voids and settling in the underfill, higher moisture resistance, better electrostatic discharge protection, and generally a higher strength and elasticity.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1A is a flip chip assembly without underfill at thermal equilibrium;

FIG. 1B is a flip chip assembly without underfill after thermal expansion;

FIG. 2A is a flip chip assembly with underfill at thermal equilibrium;

FIG. 2B is a flip chip assembly with underfill after thermal expansion;

FIG. 3 is a flip chip assembly exemplifying cracking in the chip with a hard underfill and cracking in a bump with soft underfill;

FIG. 4 is a flip chip assembly exemplifying a void near a joint of a bump and chip and settling of particles in the underfill;

FIG. 5 is a graph showing the glass transition temperature (Tg) for underfill comprising different concentrations of nanotubes;

FIG. 6 is a flip chip assembly with an underfill comprising nanotubes; and

FIG. 7 is a table summarizing physical properties of underfill comprising different concentrations of nanotubes.

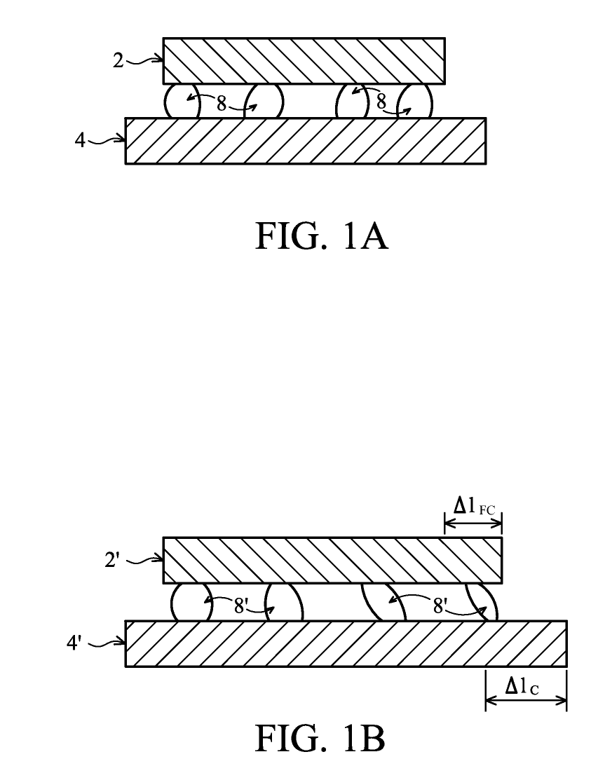

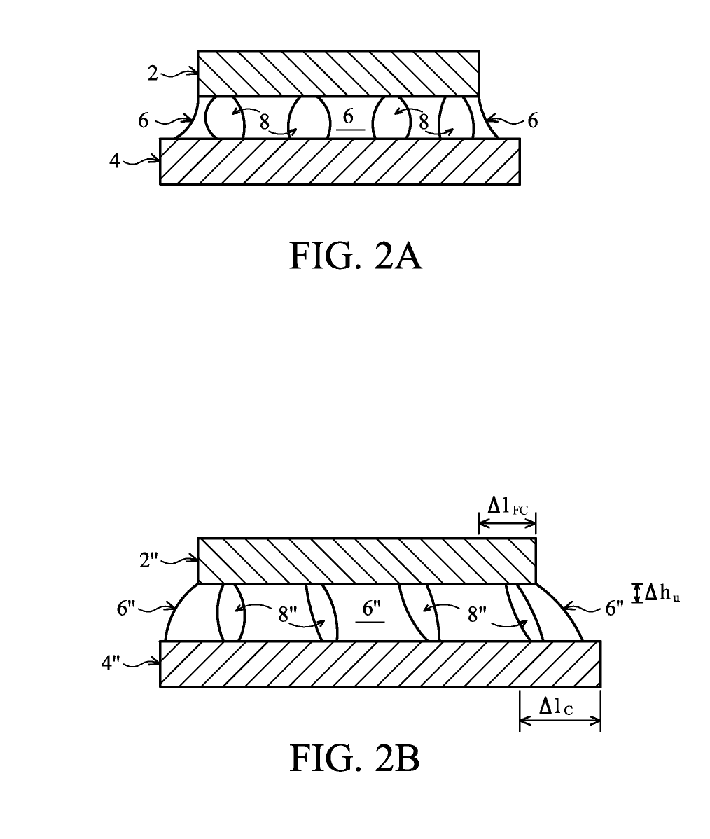

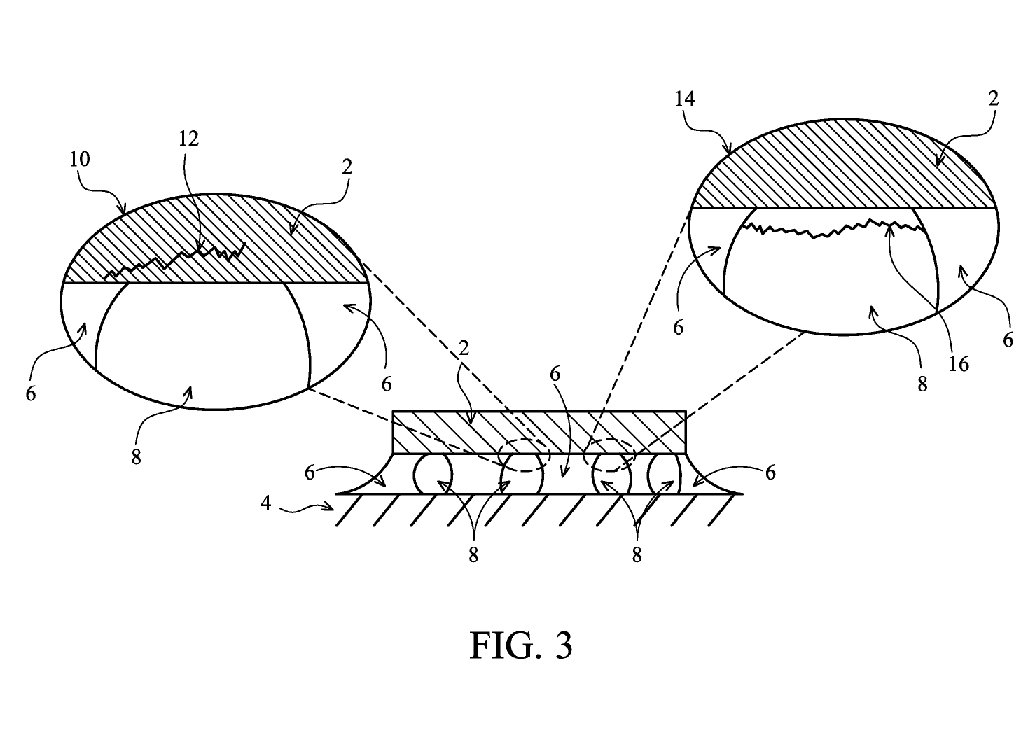

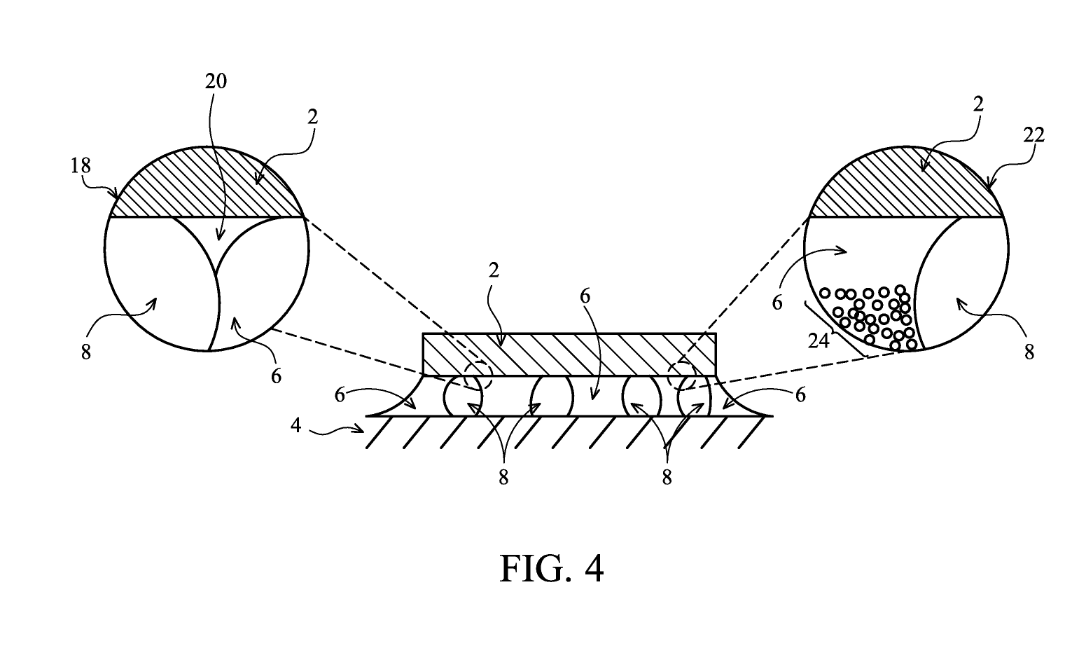

### DETAILED DESCRIPTION OF ILLUSTRATIVE EMBODIMENTS

The making and using of the present embodiments are discussed in detail below. It should be appreciated, however, that the present invention provides many applicable inventive concepts that can be embodied in a wide variety of specific contexts. The specific embodiments discussed are merely illustrative of specific ways to make and use the invention and do not limit the scope of the invention.

The present invention will be described with respect to embodiments in a specific context, namely a composite underfill in flip chip technology. The invention may also be used anywhere underfill is used, such as in a chip scale package (CSP) or a ball grid array (BGA).

Nanotubes, nanofibers, or nanoparticles are generally allotropes of carbon but can comprise carbon, carbon nitride, silicon carbon nitride, tungsten, or silver. Nanotubes are formed of a honeycomb crystal lattice shaped in a cylinder. Nanotubes generally have a diameter of around 100 nm or less. Nanofibers are similar to nanotubes except nanofibers have diameters larger than 100 nm. Nanoparticles are singular molecules of the compounds. Throughout the remainder of the description, reference will only be made to a nanostructure that includes nanotubes, nanofibers, and/or nanoparticles. Further, nanotubes and nanofibers should be understood to include all types of nanotubes and nanofibers, including armchair, zig-zag, and chiral nanotubes and nanofibers and single-walled and multi-walled nanotubes and nanofibers.

Nanostructures have unique physical properties that have sparked ongoing research into applications of the materials. Nanostructures have incredible strength and tensile properties. Also, nanostructures have very high thermal conductivity. Further, nanostructures have electrical properties similar to semiconductor materials and, in some instances, to metals.

Embodiments of the invention seek to exploit the unique properties of nanostructures by forming a composite underfill comprising a conventional epoxy matrix and nanostructures. An epoxy matrix is generally an epoxy material in which another material is embedded. The nanostructures may be a suspension within the epoxy matrix such that the nanostructures are substantially uniform throughout the epoxy matrix, although some settling may occur. The composite underfill may have an improved performance over conventional underfill by having a better coefficient of thermal expansion (CTE), by having a higher glass transition temperature, by having increased thermal integrity, by decreasing voids and settling in the underfill, and by being more resistant to the outside environment.

The composite underfill can comprise any concentration of nanostructures, but more particularly the composite underfill has nanostructures with a concentration of 0.5% to 10% by weight, or in other words, a 1:199 to 1:9 ratio of nanostructures to epoxy by weight. More specifically, the underfill has a 0.5% concentration of nanostructures.

When nanotubes are used in the nanostructures, the nanotubes can have any structure known in the art, but multi-wall nanotubes are favored over single-wall nanotubes because multi-wall nanotubes have electrical properties more closely resembling semiconductor materials. A commercial vendor of nanotubes, for example, is Shenzhen Nanotech Port Company Ltd.

Mixing nanostructures with conventional underfill results in a composite underfill that has a lower CTE to reduce thermal expansion mismatch between the underfill and the chip. With a higher concentration of nanostructures in the underfill, the nanostructures will contribute more to cause a lower CTE of the underfill. Thus, a composite underfill with a high concentration of nanostructures generally will have a lower CTE than a composite underfill with a low concentration of nanostructures.

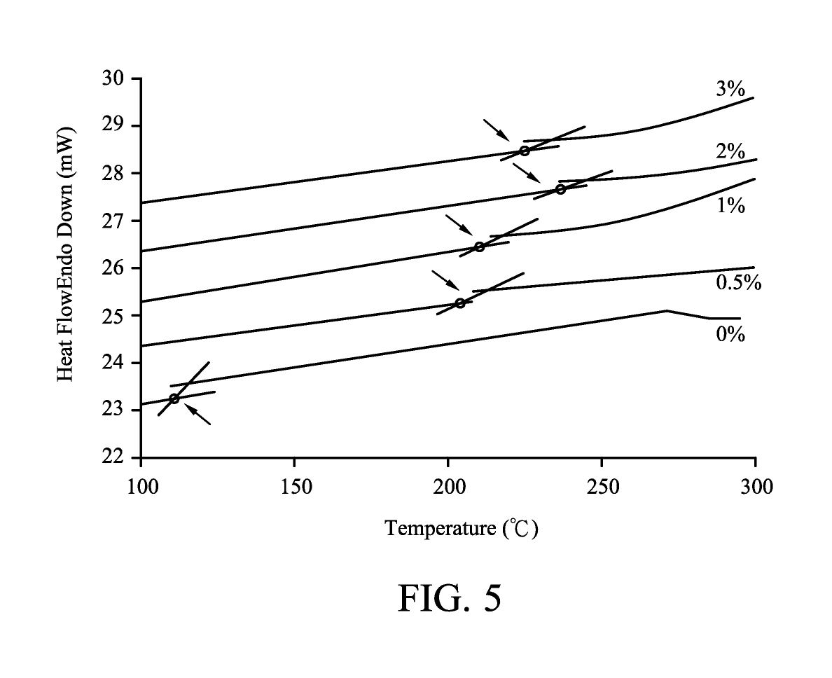

Further, nanostructures have a higher glass transition temperature that increases the overall glass transition temperature of the composite underfill. FIG. 5 shows the glass transition temperature for composite underfills with concentrations of nanostructures comprising nanotubes of 0%, 0.5%, 1%, 2%, and 3%. The discontinuity in each line, as indicated by the arrows, indicates the glass transition temperature. When no nanostructures are present in the underfill, the glass transition temperature is approximately 113° C. When the composite has a 0.5% nanostructure concentration, the Tg is approximately 201° C. The Tg for 1% is about 217° C., for 2% is about 248° C., and for 3% is about 233° C. The increase in Tg increases the strength of the underfill to better protect the solder bumps. Although an increase in Tg may have adverse effects on the low-k dielectric, these effects can be reduced by process enhancement.

The addition of nanostructures into underfill creates an overall higher thermal integrity. Generally, nanostructures have a thermal conductivity of 3000 W/m·k. This allows the nanostructures to dissipate thermal energy from the chip that in turn helps prevent thermal fatigue and cracking of the low-k dielectric.

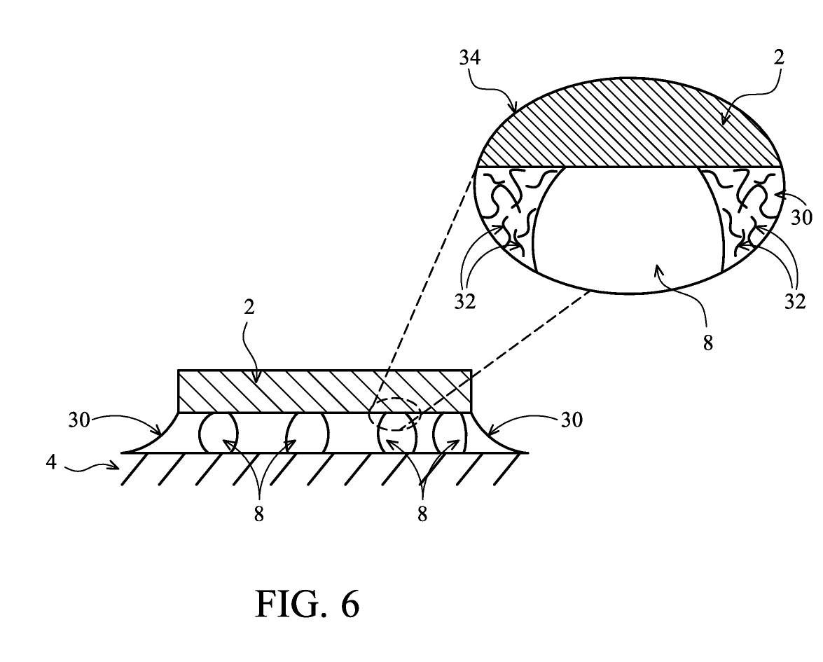

Nanostructures may fill voids and generally will not settle in the underfill. The diameter of the nanostructures allows the composite underfill to fill voids in narrow spaces between a bump pitch and chip near the bump joint. As stated above, nanotubes typically have a diameter of around 100 nm. Further, conventional underfill has particles that generally have diameters of around 5 μm, but nanoparticles generally have diameters of 100 nm. The smaller diameter of the nanostructures allows nanostructures to fill spaces that conventional underfill could not. Further, the smaller size may extend the use of a nanostructure composite underfill to much smaller packages, such as N22 technology and smaller. Also, the physical properties of nanostructures allow nanostructures to covalently bond to the epoxy to prevent settling of the nanostructures. By preventing voids and settling, the package and underfill is strengthened beyond conventional underfill. FIG. 6 illustrates the prevention of voids and settling. The composite underfill 30 is between the flip chip 2 and carrier 4 and around bumps 8. View 34 shows nanotubes 32 suspended in a matrix in the composite underfill 30.

Nanostructures mixed in an underfill will increase the underfill's moisture resistivity. Nanostructures are generally hydrophobic. This will prevent moisture from penetrating the composite underfill and causing electrical failures of the package.

An added feature of mixing nanostructures in underfill is a decrease in electrostatic discharge failures because of nanostructures' enhanced electrical conductivity. The enhanced electrical properties of nanostructures allow nanostructures to discharge static charge, minimizing any effect on the chip.

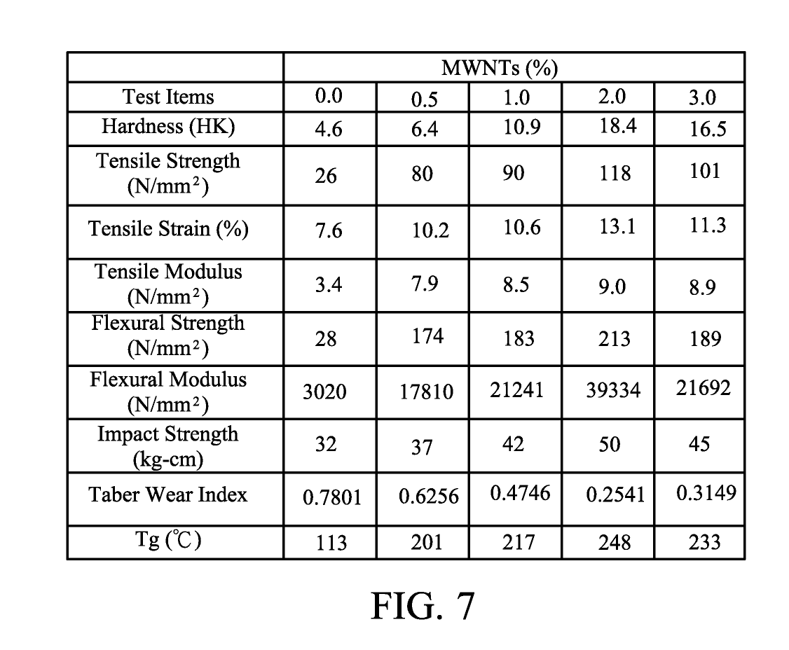

Further, nanostructures generally provide enhanced mechanical strength and elasticity for a composite underfill. FIG. 7 summarizes some properties of underfill with a concentration of nanostructures comprising multi-walled nanotubes of 0%, 0.5%, 1%, 2%, and 3%.

The mixing of the underfill and nanostructures can be done using ultrasonic force. The ultrasonic force may be between 100 revolutions per minute and 5500 revolutions per minute. The ultrasonic force can be applied by using a spin coating machine or an ultrasonic tool. A commercial example of a spin coating machine is the Chemalux from Chemat Technology, Inc., and an example of a commercial vendor of an ultrasonic tool is B2B ChinaSource Company.

The composite underfill can be applied using known processes after the carrier substrate and the flip chip have been bonded, such as by capillarity, but it can also be applied directly to the carrier substrate before the substrate and the flip chip are bonded. Once the composite underfill has been applied, the underfill may be cured to turn the underfill into a solid material using known methods, such as by applying heat, particularly between 75° C. and 200° C.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A composite underfill comprising:
an epoxy matrix applied between a substrate and a semiconductor chip; and
a suspension of nanostructures distributed within the epoxy matrix.

2. The composite underfill in claim 1, wherein the nanostructures are between 0.5 percent of the composite underfill by weight and 10 percent of the composite underfill by weight.

3. The composite underfill of claim 2, wherein the nanostructures are 0.5 percent of the composite underfill by weight.

4. The composite underfill of claim 1, wherein the nanostructures comprise carbon, carbon nitride, silicon carbon nitride, tungsten, or silver.

5. The composite underfill of claim 1, wherein the nanostructures comprise multi-wall nanotubes.

6. A semiconductor package comprising:
a semiconductor die;
a substrate, wherein the semiconductor die is electrically coupled to the substrate by solder bumps; and
a composite underfill comprising nanostructures dispersed in an epoxy, wherein the composite underfill is between the semiconductor die and the substrate and around the solder bumps.

7. The semiconductor package of claim 6, wherein the nanostructures comprise carbon, carbon nitride, silicon carbon nitride, tungsten, or silver.

8. The semiconductor package of claim 6, wherein the nanostructures comprise multi-wall nanotubes.

9. The semiconductor package of claim 6, wherein a ratio of the nanostructures to the epoxy is between 1:199 and 1:9 by weight.

10. The semiconductor package of claim 9, wherein the ratio of nanostructures to the epoxy is 1:199 by weight.

11. A semiconductor package comprising:
a semiconductor chip;
a carrier, wherein the semiconductor chip is bonded to the carrier; and
a composite underfill comprising a plurality of nanostructures dispersed in an epoxy medium between the carrier and the semiconductor chip.

12. The semiconductor package of claim 11, wherein the plurality of nanostructures is between 0.5 percent and 10 percent by weight of the composite underfill.

13. The semiconductor package of claim 12, wherein the plurality of nanostructures is 0.5 percent by weight of the composite underfill.

14. The semiconductor package of claim 11, wherein the plurality of nanostructures is a plurality of multi-wall nanotubes.

15. A method for creating a semiconductor package comprising:
creating solder bumps on a semiconductor chip;
bonding the bumps to a carrier;
applying a composite underfill comprising nanostructures; and
curing the composite underfill.

16. The method of claim 15, wherein the composite underfill comprises nanostructures that are between 0.5 percent and 10 percent by weight of the composite underfill.

17. The method of claim 16, wherein the composite underfill comprises nanostructures that are 0.5 percent of the composite underfill.

18. The method of claim 15, wherein applying the composite underfill comprises applying the composite underfill directly to the carrier before bonding the bumps to the carrier.

19. The method of claim 15, wherein applying the composite underfill comprises applying the composite underfill between the semiconductor chip and the carrier and around the bumps after bonding the bumps to the carrier.

20. The method of claim 15, wherein curing the composite underfill comprises heating the composite underfill to a temperature between 75° C. and 200° C.

21. The method of claim 15, wherein the semiconductor chip includes a flip chip.
